(19) United States
(12) Patent Application Publication
(10) Pub. No.: US 2024/0421201 A1
(43) Pub. Date: Dec. 19, 2024

(54) TRENCH CONNECTION OVER DISCONNECTED EPITAXIAL STRUCTURE USING DIRECTED SELF-ASSEMBLY

(71) Applicant: Intel Corporation, Santa Clara, CA (US)

(72) Inventors: Leonard P. GULER, Hillsboro, OR (US); Thomas O’BRIEN, Portland, OR (US); Charles H. WALLACE, Portland, OR (US); Anindya DASGUPTA, Portland, OR (US)

(21) Appl. No.: 18/336,323

(22) Filed: Jun. 16, 2023

(51) Int. Cl. H01L 29/417; H01L 29/06; H01L 29/08; H01L 29/40; H01L 29/423; H01L 29/778; H01L 29/786

(52) U.S. Cl. CPC H01L 29/41733; H01L 29/0665; H01L 29/0847; H01L 29/401; H01L 29/41775; H01L 29/42392; H01L 29/778; H01L 29/78696

(57) ABSTRACT

Embodiments described herein may be related to apparatuses, processes, systems, and/or techniques for creating flyover trench connectors within a transistor structure, where a first portion of the trench connector is electrically coupled with a first epitaxial structure and where a second portion of the trench connector extends above but is not electrically coupled with a second epitaxial structure. Other embodiments may be described and/or claimed.

### FIELD

Embodiments of the present disclosure generally relate to the field of semiconductor manufacturing, and in particular to forming trench connectors in transistor structures.

### BACKGROUND

Continued growth in virtual machines, cloud computing, and portable devices will continue to increase the demand for high density transistors within chips and packages. In addition, there will be an increased need for high quality interconnects between transistor components that have a reduced cell size.

### BRIEF DESCRIPTION OF THE DRAWINGS

FIGS. 1A-1J show perspective views of stages in a manufacturing process for creating a transistor structure that includes flyover trench connectors created using a directed self-assembly (DSA) process, in accordance with various embodiments.

FIGS. 2A-2E show end views of stages in a manufacturing process for forming a dielectric on top of a gate using a DSA process, in accordance with various embodiments.

FIG. 3 illustrates an example process for manufacturing a voltage contrast structure, in accordance with various embodiments.

FIG. 4 illustrates a computing device in accordance with one implementation of the invention.

FIG. 5 illustrates an interposer that includes one or more embodiments of the invention.

### DETAILED DESCRIPTION

Embodiments described herein may be related to apparatuses, processes, systems, and/or techniques for creating trench connectors within a transistor structure, where a first portion of the trench connector is electrically coupled with a first epitaxial structure and where a second portion of the trench connector extends above a second epitaxial structure. In embodiments, the trench connector is not electrically coupled with the second epitaxial structure. In embodiments, this design of the trench connector may be referred to as a flyover trench connector.

In embodiments, during manufacture, DSA techniques may be used to form a material that includes one or more polymers on top of a gate structure, where the material may be subsequently used to pattern a dielectric, for example a nitride, on top of the gate structure. In embodiments, this approach may allow a trench connector to be formed, where a bottom surface of the second portion of the trench connector above the separate epitaxial structure may be in a same plane as a top surface of the gate. In embodiments, the DSA techniques used to create the dielectric on top of the gate structure will result in a width of the dielectric on top of the gate being greater than a width of the gate.

In embodiments, the DSA techniques may also be applied subsequent to gate cuts made within the transistor structure to electrically isolate portions of the gate from each other. In these embodiments, where the gate cut is less than 30 nanometers (nm), the DSA techniques will span the gate cuts, and the dielectric on the resulting plurality of gates will be uniform.

Using flyover trench connectors will become increasingly valuable as transistor cell size continues to shrink. Flyover trench connector techniques may be used to increase the number of metal tracks that may be used to electrically interconnect trench connectors that are electrically coupled with different epitaxial structures with each other. In embodiments, by increasing the length of the trench connector, this increases the number of points of contact along the length of the trench connector to which various metal tracks may be electrically coupled.

In embodiments, this may become increasingly important as the overall cell size of transistor structures continues to shrink. Using these techniques described herein may allow the overall number of metal tracks to stay the same even though cell sizes continues to shrink.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

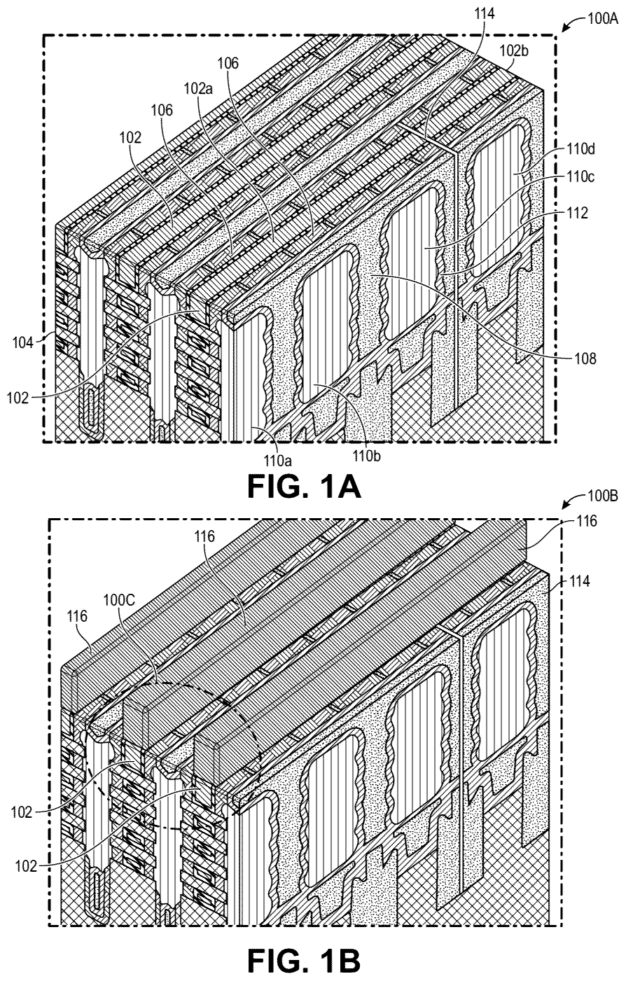

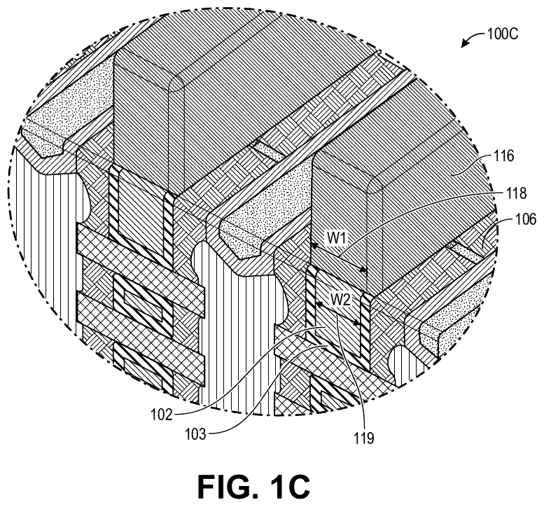

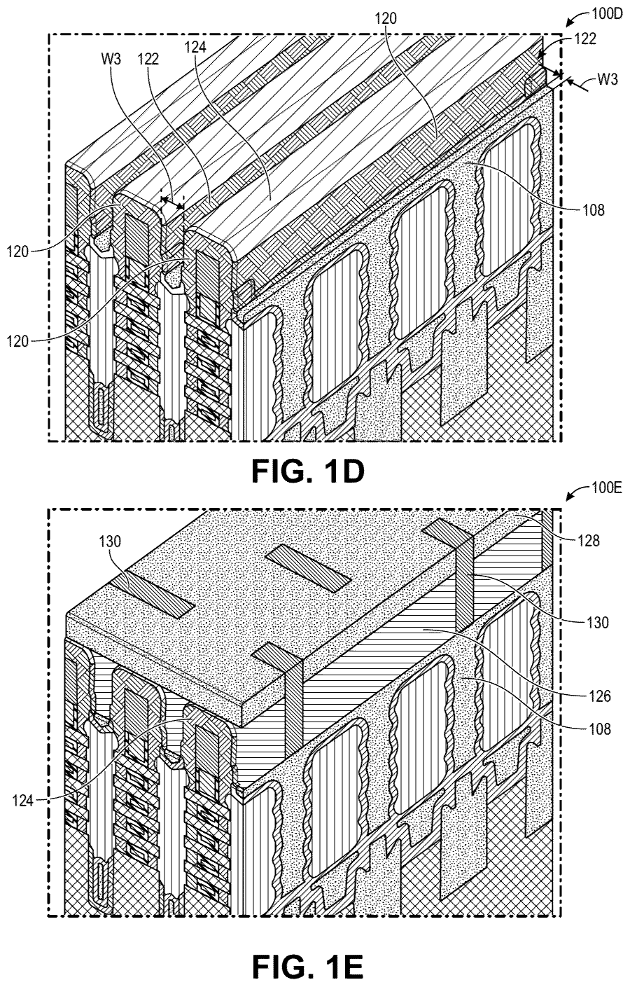

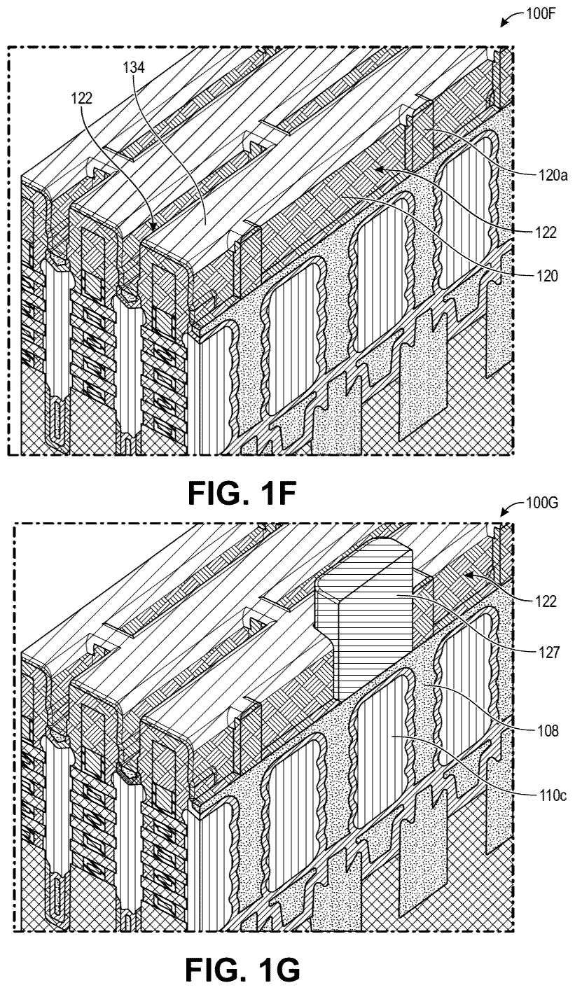

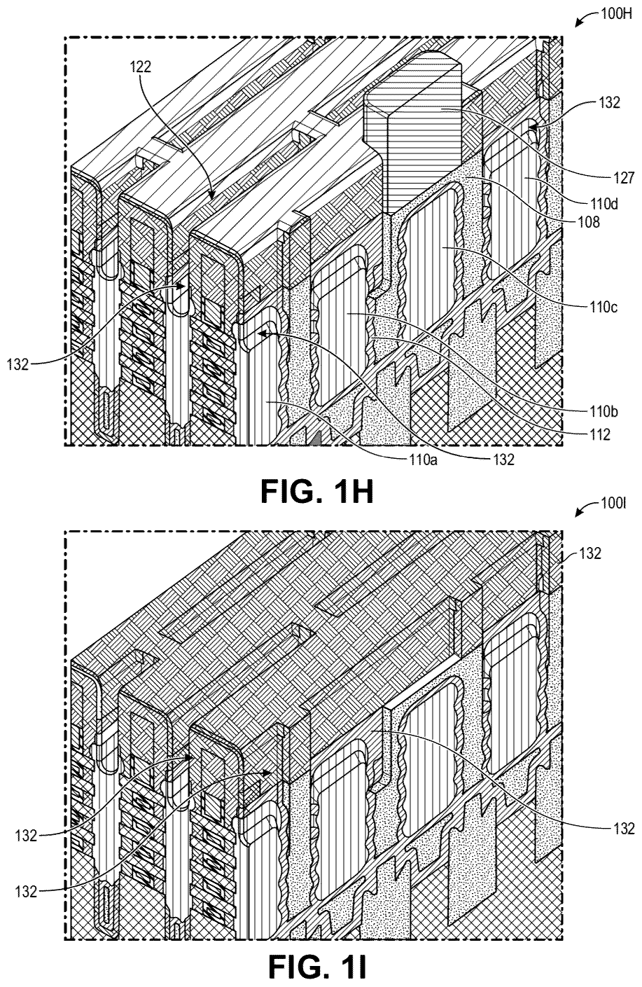

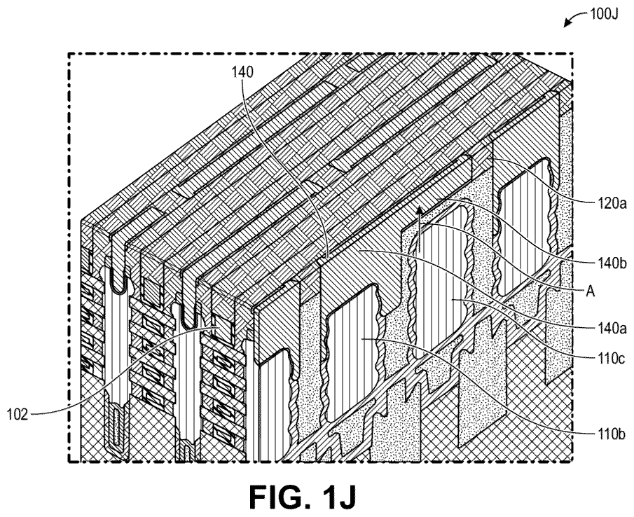

FIGS. 1A-1J show perspective views of stages in a manufacturing process for creating a transistor structure that includes flyover trench connectors created using a DSA process, in accordance with various embodiments. FIG. 1A shows a perspective view of a stage in the manufacturing process of transistor structure 100A. Transistor structure 100A has already been substantially formed, and includes a plurality of gates 102 that may be on nanoribbons 104. A dielectric 106 may be on either side of the gate 102, with another dielectric 108 next to the dielectric 106.

In embodiments, epitaxial structures 110a, 110b, 110c, 110d may be below the dielectric 106, 108, and may be at least partially below the gate 102. In embodiments, the epitaxial structures 110a, 110b, 110c, 110d may serve as sources or drains. In embodiments, a spacer 112 may surround at least a portion of the epitaxial structures 110a, 110b, 110c, 110d to isolate them from the dielectric 108.

In embodiments, there may be one or more gate cuts 114 that electrically separate a gate 102 into a first gate 102a and into a second gate 102b. In embodiments, the gate cut 114 may include a dielectric, or some other material used to electrically isolate the first gate 102a and the second gate 102b from each other. In embodiments, a width of the gate cut 114 may be less than 30 nm.

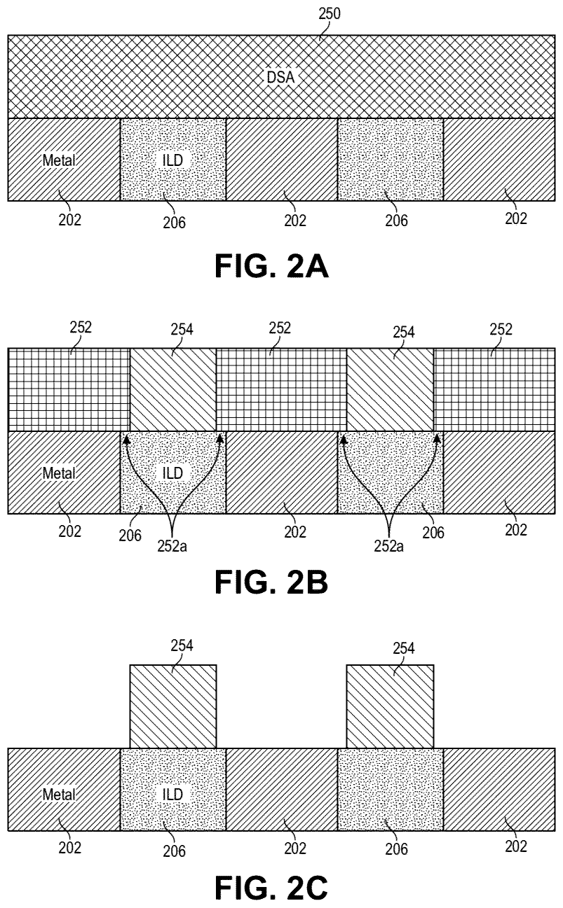

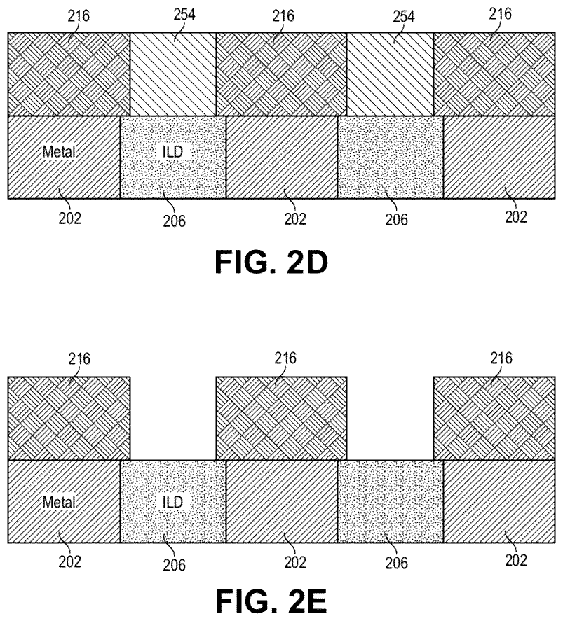

FIG. 1B shows a perspective view of a stage in the manufacturing process of the transistor structure 100B, which may be similar to transistor structure 100A of FIG. 1A. In embodiments a gate interlayer dielectric (GILA) 116 may be formed over the gates 102, using a DSA process. In embodiments, the GILA 116 may be referred to as a gate protection layer. The DSA process is described in greater detail with respect to FIGS. 2A-2E below. Note that as a result of the DSA process, a width of the GILA 116 may be larger than a width of the gate 102. This may be seen in greater detail in area 100C of FIG. 1C.

FIG. 1C shows an enlargement of area 100C of FIG. 1B. In embodiments, due to the application of the DSA process, the GILA 116 covers the surface of the gate 102, and a first width w1 118 of the GILA 116 is greater than a second width w2 119 of the gate 102. Note that in embodiments, the GILA 116 may overlap onto a dielectric 103 that may surround a portion of the gate 102. In embodiments, the GILA 116 may also overlap onto a portion of the dielectric 106.

FIG. 1D shows a perspective view of a stage in the manufacturing process of transistor structure 100D, which may be similar to transistor structure 100B of FIG. 1B, where a liner 120 is placed on the GILA 116. In embodiments, the liner 120 may cover the top and the sides of the GILA 116. In embodiments, a thickness of a liner 120 may be selected in order to adjust a desired width w3 between trenches 122 within the transistor structure 100D. In embodiments, the width w3 between the trenches 122 may determine a width of the subsequently created trench connector.

In embodiments, a helmet 124 may be placed on the liner 120, and may be placed over the GILA 116. In embodiments, the helmet 124 may include a selected one or more of titanium nitride, silicon, titanium oxide, silicon nitride, or some other oxide. In some embodiments, the helmet 124 may include a same material as the dielectric 108. Subsequently, an etch or some other removal technique may be applied to etch the liner 120 that is not underneath the helmet 124 to form the trenches 122. In embodiments, the bottom of the trench 122 may expose a portion of the dielectric 108. In embodiments, the helmet 124 does not cover at least a portion of the sides of the trenches 122.

FIG. 1E shows a perspective view of a stage in the manufacturing process of transistor structure 100E, which may be similar to transistor structure 100D of FIG. 1D, where a carbon hard mask 126 is placed on the dielectric 108, on the helmet 124, and on the liner 120. In embodiments, the carbon hard mask 126 may include amorphous carbon film (ACF) material. In embodiments, a dielectric layer 128, which may include an oxide material, may be placed on the carbon hard mask 126.

In embodiments, plugs 130 may be formed within the transistor structure 100E and may be filled with a dielectric material. In embodiments, the plugs 130 may extend through the dielectric layer 128, and through the carbon hard mask 126. In embodiments, these plugs 130 will later form disconnection areas for later formed trench connectors, for example to electrically separate source epitaxial structures from drain epitaxial structures. In embodiments, the plugs 130 may extend to the dielectric layer 108, or may extend into the dielectric layer 108.

FIG. 1F shows a perspective view of a stage in the manufacturing process of transistor structure 100F, which may be similar to transistor structure 100E of FIG. 1E, where an etching/ash process may be used to remove the dielectric layer 128 and the carbon hard mask 126 shown in FIG. 1E, exposing the liner 120. Note that additional portions of the liner 120a between the trenches 122, formed by the plugs 130 of FIG. 1E, will form disconnection areas for the later formed trench connectors described further below. In embodiments, a helmet 134, which may be similar to helmet 124 of FIG. 1D, may be placed on the liner 120 and the additional portions of the liner 120a in preparation for subsequent etching.

FIG. 1G shows a perspective view of a stage in the manufacturing process of transistor structure 100G, which may be similar to transistor structure 100F of FIG. 1F, where a plug 127 is placed over a portion of epitaxial structure 110C, and within one of the trenches 122. The plug 127 may be formed using techniques conventionally known in the art. In embodiments, the plug 127 will prevent the dielectric material 108 that is over the epitaxial structure 110c from being etched away in subsequent manufacturing stages.

FIG. 1H shows a perspective view of a stage in the manufacturing process of transistor structure 100H, which may be similar to transistor structure 100G of FIG. 1G, where a subsequent etch is done to etch away at least a portion of epitaxial structures 110a, 110c, 110d, and at least a portion of the dielectric 108, to create cavities 132. Note that at least a portion of the spacer 112 surrounding the epitaxial structure 110b has also been etched away. Note that in subsequent steps, trench connectors may be formed in the cavities 132.

FIG. 1I shows a perspective view of a stage in the manufacturing process of transistor structure 100I, which may be similar to transistor structure 100H of FIG. 1H, where the plug 127 shown in FIG. 1H is removed and the helmet 134 of FIG. 1F is removed.

FIG. 1J shows a perspective view of a stage in the manufacturing process of transistor structure 100J, which may be similar to transistor structure 100I of FIG. 1I, where a plurality of trench connectors, such as trench connector 140, may be placed into the cavities 132 described above with respect to FIG. 1H. In embodiments, the trench connectors may be printed into the cavities 132. Note that a first portion of a trench connector 140a may be directly electrically coupled with a portion of the epitaxial structure 110b, and a second portion of the trench connector 140b, which may be referred to as a flyover, may be above but not directly electrically coupled with the epitaxial structure 110C. As a result, in embodiments, a larger contact area is formed at the top of the trench connector 140 by combining the area of the first portion of the trench connector 140a and the second portion of the trench connector 140b. In embodiments, trench connector 140 may be referred to as a flyover trench connector.

In embodiments, one end of the trench connector 140 will be at additional portions of the liner 120a. In addition, it should be noted that, in embodiments, that these techniques may result in a bottom “A” of the second portion of the trench connector 140b being in a same plane as a top of the gate 102.

FIGS. 2A-2E show end views of stages in a manufacturing process for forming a dielectric on top of a gate using a DSA process, in accordance with various embodiments. In embodiments, the process shown with respect to FIGS. 2A-2E may be used to implement one or more of the manufacturing stages that may be applied to an embodiment described above in FIG. 1A to produce an embodiment described above that may be similar to FIG. 1B.

FIG. 2A shows an end view of a stage in the manufacturing process where a plurality of metal structures 202, which may be similar to gate 102 of FIG. 1A, may be separated by dielectric structures 206, which may be similar to dielectric 106 of FIG. 1A. In embodiments, a polymer 250 may be applied on top of the metal structures 202 and the dielectric structures 206. In embodiments, the polymer 250 may be applied using a spinning process.

FIG. 2B shows an end view of a stage in the manufacturing process where heat is applied. As a result, the polymer 250 changes its molecular structure into a first set of regions 252 that are substantially above the metal structures 202, and a second set of regions 254 that are above the dielectric structures 206. In embodiments, the first set of regions 252 may be the result of self-aligning molecules that bonded to the metal in the metal structures 202, and as a result form similar self-aligning molecules throughout the depth of the first set of regions 252. In embodiments, the result of the self-aligning process may result in an extension 252a of the first set of regions to overlap over at least part of the dielectric structures 206. The second set of regions 254, which may be substantially above the dielectric structures 206, may not have similarly self-aligned molecules.

FIG. 2C shows an end view of a stage in the manufacturing process where an etching process may be applied to remove the first set of regions 252 that are substantially above the metal structures 202, leaving the second set of regions 254 intact.

FIG. 2D shows an end view of a stage in the manufacturing process where dielectric 216 may be applied above the metal structures 202. In embodiments, the dielectric 216, which may be a nitride, may be similar to the GILA 116 of FIG. 1B. In embodiments, the second set of regions 254 may be used to define a boundary of the dielectric 216, and therefore allow for an overlap of the dielectric 216 above the dielectric structures 206.

FIG. 2E shows an end view of a stage in the manufacturing process where another etch is performed to remove the second set of regions 254 of FIG. 2D to expose the dielectric structures 206.

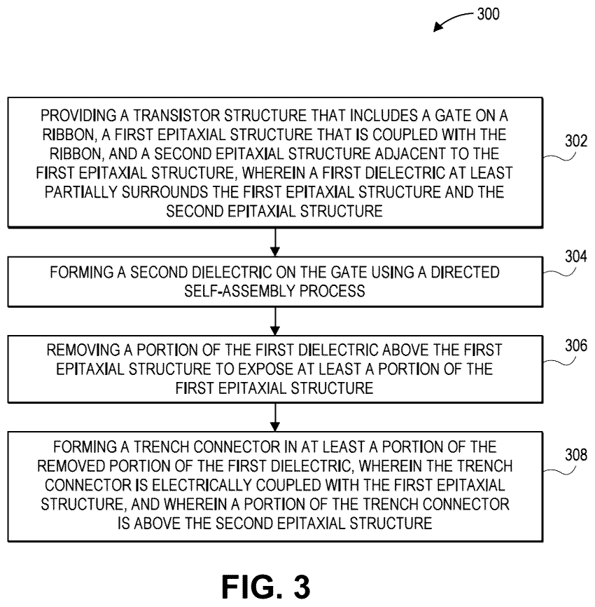

FIG. 3 illustrates an example process for manufacturing a voltage contrast structure, in accordance with various embodiments. Process 300 may be performed using the apparatus, systems, tools, techniques, and processes described herein, and particular with respect to FIGS. 1A-2E.

At block 302, the process may include providing a transistor structure that includes a gate on a ribbon, a first epitaxial structure that is coupled with the ribbon, and a second epitaxial structure adjacent to the first epitaxial structure, wherein a first dielectric at least partially surrounds the first epitaxial structure and the second epitaxial structure. In embodiments, the transistor structure may be similar to transistor structure 100A of FIG. 1A. In embodiments, the gate may be similar to gate 102, the first epitaxial structure may be similar to epitaxial structure 110b, and the second epitaxial structure may be similar to epitaxial structure 110c of FIG. 1A. In embodiments, the first dielectric may be similar to dielectric 108 of FIG. 1A.

At block 304, the process may further include forming a second dielectric on the gate using a directed self-assembly process. In embodiments, the second dielectric may be similar to the GILA 116 of FIG. 1B.

At block 306, the process may further include removing a portion of the first dielectric above the first epitaxial structure to expose at least a portion of the first epitaxial structure.

At block 308, the process may further include forming a trench connector in at least a portion of the removed portion of the first dielectric, wherein the trench connector is electrically coupled with the first epitaxial structure, and wherein a portion of the trench connector is above the second epitaxial structure. In embodiments, the trench connector may be similar to trench connector 140 of FIG. 1J, where the second portion of the trench connector 140b may be above the epitaxial structure 110C of FIG. 1J.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around-gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

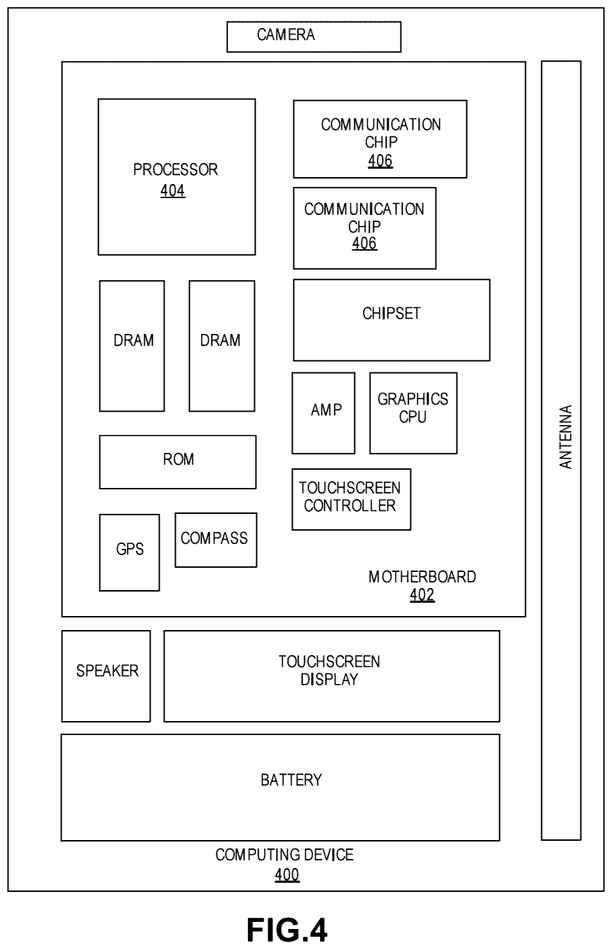

FIG. 4 illustrates a computing device 400 in accordance with one implementation of the invention. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of the invention, the integrated circuit die of the communication chip includes one or more devices, such as MOS-FET transistors built in accordance with implementations of the invention.

In further implementations, another component housed within the computing device 400 may contain an integrated circuit die that includes one or more devices, such as MOS-FET transistors built in accordance with implementations of the invention.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

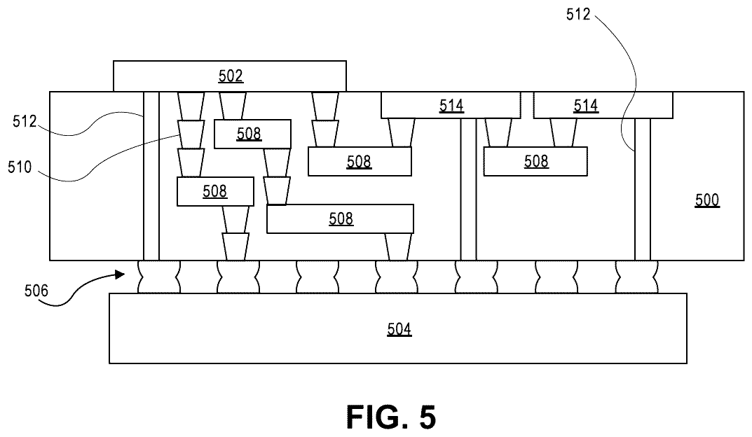

FIG. 5 illustrates an interposer 500 that includes one or more embodiments of the invention. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the invention, apparatuses or processes disclosed herein may be used in the fabrication of interposer 500.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a transistor structure comprising: a gate, wherein the gate includes a bottom surface, a top surface opposite the bottom surface, a first side, and a second side opposite the first side, wherein the first side of the gate and the second side of the gate are substantially perpendicular to the top surface of the gate; a dielectric layer with a bottom surface of the dielectric layer on the top surface of the gate, wherein the dielectric layer includes a top surface opposite the bottom surface, a first side, and a second side opposite the first side, wherein the first side of the dielectric layer and the second side of the dielectric layer are substantially perpendicular to the bottom surface of the dielectric layer; and wherein a first width of the bottom surface of the dielectric layer between the first side of the dielectric layer and the second side of the dielectric layer is greater than a second width of the top surface of the gate between the first side of the gate and the second side of the gate.

Example 2 includes the transistor structure of example 1, further comprising a first epitaxial structure and a second epitaxial structure, wherein the first epitaxial structure and the second epitaxial structure are adjacent to each other and are below the top surface of the gate.

Example 3 includes the transistor structure of example 2, further comprising: a trench connector on at least a portion of the first epitaxial structure, wherein the trench connector is electrically coupled with the first epitaxial structure; and wherein a portion of the trench connector is above at least a portion of the second epitaxial structure, and wherein the trench connector is not electrically coupled with the second epitaxial structure.

Example 4 includes the transistor structure of example 3, wherein the portion of the trench connector that is above the portion of the second epitaxial structure further includes a top surface and a bottom surface opposite the top surface, wherein the bottom surface of the portion of the trench connector is proximate to the second epitaxial structure, and wherein the bottom surface of the portion of the trench connector is in a same plane as the top surface of the gate.

Example 5 includes the transistor structure of examples 3 or 4, further comprising an electrical insulator material separating the second epitaxial structure from the trench connector.

Example 6 includes the transistor structure of examples 3, 4, or 5, wherein the first epitaxial structure is directly physically coupled with the trench connector.

Example 7 includes the transistor structure of examples 3, 4, 5, or 6, wherein the portion of the trench connector is a first portion of the trench connector; and further comprising a recess in the first epitaxial structure, wherein a second portion of the trench connector is placed into the recess in the first epitaxial structure.

Example 8 includes the transistor structure of example 7, wherein the second epitaxial structure is surrounded by a spacer that is between the second epitaxial structure and the trench connector.

Example 9 includes the transistor structure of examples 3, 4, 5, 6, 7, or 8, wherein the trench connector is printed onto the transistor structure.

Example 10 includes the transistor structure of examples 1, 2, 3, 4, 5, 6, 7, 8, or 9, wherein the dielectric layer is applied on the gate using a directed self-assembly (DSA) process.

Example 11 includes the transistor structure of examples 1, 2, 3, 4, 5, 6, 7, 8, 9, or 10, wherein the gate includes a selected one or more of: a polysilicon, a silicide material, or a metal composite.

Example 12 is an apparatus comprising: electrical circuitry; and a transistor structure coupled with the electrical circuitry, the transistor structure comprising: a gate with a bottom surface and a top surface opposite the bottom surface; a first epitaxial structure and a second epitaxial structure that are both at least partially below the gate, wherein the first epitaxial structure and the second epitaxial structure are adjacent to each other; a trench connector with a top surface and a bottom surface opposite the top surface, wherein a first portion of the bottom surface of the trench connector is directly electrically coupled with a portion of the first epitaxial structure, and wherein a second portion of the bottom surface of the trench connector extends above at least part of the second epitaxial structure, wherein the trench connector is not directly electrically coupled with the second epitaxial structure; and wherein the second portion of the bottom surface of the trench connector is in a same plane as the top surface of the gate.

Example 13 includes the apparatus of example 12, wherein the gate includes a first side and a second side opposite the first side, wherein the first side and the second side are substantially perpendicular to the bottom surface of the gate or to the top surface of the gate; and further comprising: a dielectric on top of the gate, the dielectric having a first side and a second side opposite the first side, wherein the first side and the second side are substantially parallel to the first side of the gate or the second side of the gate; and wherein a first width the gate between the first side of the gate in the second side of the gate is less than a second width of the dielectric between the first side of the dielectric and the second side of the dielectric.

Example 14 includes the apparatus of example 13, wherein the dielectric is applied using a directed self-assembly process.

Example 15 includes the apparatus of examples 13 or 14, wherein the dielectric includes one or more polymers, and wherein an orientation of molecules in the one or more polymers are substantially a same orientation.

Example 16 includes the apparatus of examples 12, 13, 14, or 15, wherein the first epitaxial structure is at least partially recessed, and wherein at least a portion of the first portion of the bottom surface of the trench connector is in the recess.

Example 17 includes the apparatus of example 16, wherein the at least a portion of the first portion of the bottom surface of the trench connector is directly physically coupled with the first epitaxial structure.

Example 18 is a method comprising: providing a transistor structure that includes a gate on a ribbon, a first epitaxial structure that is coupled with the ribbon, and a second epitaxial structure adjacent to the first epitaxial structure, wherein a first dielectric at least partially surrounds the first epitaxial structure and the second epitaxial structure; forming a second dielectric on the gate using a directed self-assembly process; removing a portion of the first dielectric above the first epitaxial structure to expose at least a portion of the first epitaxial structure; and forming a trench connector in at least a portion of the removed portion of the first dielectric, wherein the trench connector is electrically coupled with the first epitaxial structure, and wherein a portion of the trench connector is above the second epitaxial structure.

Example 19 includes the method of example 18, wherein removing a portion of the first dielectric above the first epitaxial structure further includes exposing at least a portion of the first epitaxial structure.

Example 20 includes the method of examples 18 or 19, wherein forming the trench connector further comprises forming the trench connector using a printing process.

What is claimed is:

1. A transistor structure comprising:
a gate, wherein the gate includes a bottom surface, a top surface opposite the bottom surface, a first side, and a second side opposite the first side, wherein the first side of the gate and the second side of the gate are substantially perpendicular to the top surface of the gate;
a dielectric layer with a bottom surface of the dielectric layer on the top surface of the gate, wherein the dielectric layer includes a top surface opposite the bottom surface, a first side, and a second side opposite the first side, wherein the first side of the dielectric layer and the second side of the dielectric layer are substantially perpendicular to the bottom surface of the dielectric layer; and
wherein a first width of the bottom surface of the dielectric layer between the first side of the dielectric layer and the second side of the dielectric layer is greater than a second width of the top surface of the gate between the first side of the gate and the second side of the gate.

2. The transistor structure of claim 1, further comprising a first epitaxial structure and a second epitaxial structure, wherein the first epitaxial structure and the second epitaxial structure are adjacent to each other and are below the top surface of the gate.

3. The transistor structure of claim 2, further comprising:
a trench connector on at least a portion of the first epitaxial structure, wherein the trench connector is electrically coupled with the first epitaxial structure; and
wherein a portion of the trench connector is above at least a portion of the second epitaxial structure, and wherein the trench connector is not electrically coupled with the second epitaxial structure.

4. The transistor structure of claim 3, wherein the portion of the trench connector that is above the portion of the second epitaxial structure further includes a top surface and a bottom surface opposite the top surface, wherein the bottom surface of the portion of the trench connector is proximate to the second epitaxial structure, and wherein the bottom surface of the portion of the trench connector is in a same plane as the top surface of the gate.

5. The transistor structure of claim 3, further comprising an electrical insulator material separating the second epitaxial structure from the trench connector.

6. The transistor structure of claim 3, wherein the first epitaxial structure is directly physically coupled with the trench connector.

7. The transistor structure of claim 3, wherein the portion of the trench connector is a first portion of the trench connector; and further comprising a recess in the first epitaxial structure, wherein a second portion of the trench connector is placed into the recess in the first epitaxial structure.

8. The transistor structure of claim 7, wherein the second epitaxial structure is surrounded by a spacer that is between the second epitaxial structure and the trench connector.

9. The transistor structure of claim 3, wherein the trench connector is printed onto the transistor structure.

10. The transistor structure of claim 1, wherein the dielectric layer is applied on the gate using a directed self-assembly (DSA) process.

11. The transistor structure of claim 1, wherein the gate includes a selected one or more of: a polysilicon, a silicide material, or a metal composite.

12. An apparatus comprising:
electrical circuitry; and
a transistor structure coupled with the electrical circuitry, the transistor structure comprising:
a gate with a bottom surface and a top surface opposite the bottom surface;
a first epitaxial structure and a second epitaxial structure that are both at least partially below the gate, wherein the first epitaxial structure and the second epitaxial structure are adjacent to each other;
a trench connector with a top surface and a bottom surface opposite the top surface, wherein a first portion of the bottom surface of the trench connector is directly electrically coupled with a portion of the first epitaxial structure, and wherein a second portion of the bottom surface of the trench connector extends above at least part of the second epitaxial structure, wherein the trench connector is not directly electrically coupled with the second epitaxial structure; and
wherein the second portion of the bottom surface of the trench connector is in a same plane as the top surface of the gate.

13. The apparatus of claim 12, wherein the gate includes a first side and a second side opposite the first side, wherein the first side and the second side are substantially perpendicular to the bottom surface of the gate or to the top surface of the gate; and further comprising:
a dielectric on top of the gate, the dielectric having a first side and a second side opposite the first side, wherein the first side and the second side are substantially parallel to the first side of the gate or the second side of the gate; and
wherein a first width the gate between the first side of the gate in the second side of the gate is less than a second width of the dielectric between the first side of the dielectric and the second side of the dielectric.

14. The apparatus of claim 13, wherein the dielectric is applied using a directed self-assembly process.

15. The apparatus of claim 13, wherein the dielectric includes one or more polymers, and wherein an orientation of molecules in the one or more polymers are substantially a same orientation.

16. The apparatus of claim 12, wherein the first epitaxial structure is at least partially recessed, and wherein at least a portion of the first portion of the bottom surface of the trench connector is in the recess.

17. The apparatus of claim 16, wherein the at least a portion of the first portion of the bottom surface of the trench connector is directly physically coupled with the first epitaxial structure.

18. A method comprising:
providing a transistor structure that includes a gate on a ribbon, a first epitaxial structure that is coupled with the ribbon, and a second epitaxial structure adjacent to the first epitaxial structure, wherein a first dielectric at least partially surrounds the first epitaxial structure and the second epitaxial structure;
forming a second dielectric on the gate using a directed self-assembly process;
removing a portion of the first dielectric above the first epitaxial structure to expose at least a portion of the first epitaxial structure; and
forming a trench connector in at least a portion of the removed portion of the first dielectric, wherein the trench connector is electrically coupled with the first epitaxial structure, and wherein a portion of the trench connector is above the second epitaxial structure.

19. The method of claim 18, wherein removing a portion of the first dielectric above the first epitaxial structure further includes exposing at least a portion of the first epitaxial structure.

20. The method of claim 18, wherein forming the trench connector further comprises forming the trench connector using a printing process.
